(19) United States
(12) Patent Application Publication
(10) Pub. No.: US 2026/0177605 A1
(43) Pub. Date: Jun. 25, 2026

(54) KELVIN SCHEME PACKAGE

(71) Applicant: SEMICONDUCTOR COMPONENTS INDUSTRIES, LLC, Scottsdale, AZ (US)

(72) Inventors: James Joseph VICTORY, Trabuco Canyon, CA (US); Lizhen ZHANG, Chandler, AZ (US); Silnore Tejero SABANDO, Lapulapu City (PH); Alan David FINKEL, Chandler, AZ (US)

(73) Assignee: SEMICONDUCTOR COMPONENTS INDUSTRIES, LLC, Scottsdale, AZ (US)

(21) Appl. No.: 19/420,258

(22) Filed: Dec. 15, 2025

Related U.S. Application Data
(60) Provisional application No. 63/737,315, filed on Dec. 20, 2024.

(51) Int. Cl. G01R 31/27; G01R 19/00; G01R 31/26; H10D 62/832; H10D 80/20; H10W 70/40; H10W 72/50; H10W 90/00; H10W 90/10

(52) U.S. Cl. CPC G01R 31/27; G01R 19/0092; H10D 62/8325; H10W 70/464; H10W 72/547; H10W 90/10; H10W 90/753; H10W 90/756; G01R 31/2608; G01R 31/2621; G01R 31/2632; H10D 80/231; H10D 80/251

(57) ABSTRACT

Implementations of semiconductor packages may include a plurality of semiconductor die, a Kelvin bar, and an isolated pad. The Kelvin bar may be electrically coupled to the plurality of semiconductor die through the isolated pad. The Kelvin bar may be electrically coupled with a Kelvin pin. Implementations of the semiconductor packages may include a substrate. The plurality of semiconductor die may be coupled over the substrate.

### CROSS REFERENCE TO RELATED APPLICATIONS

This document claims the benefit of the filing date of U.S. Provisional Patent Application 63/737,315, entitled “Kelvin Scheme Package” to James Victory which was filed on Dec. 20, 2024, the disclosure of which is hereby incorporated entirely herein by reference.

### BACKGROUND

### 1. Technical Field

Aspects of this document relate generally to semiconductor packages that utilize internal Kelvin sensing. More specific implementations involve semiconductor packages that include semiconductor die containing silicon carbide.

### 2. Background

Semiconductor packages may include one or more semiconductor die. The semiconductor packages may also include Kelvin sensing systems that measure current associated with the semiconductor package.

### SUMMARY

Implementations of semiconductor packages may include a plurality of semiconductor die, a Kelvin bar, and an isolated pad. The Kelvin bar may be electrically coupled to the plurality of semiconductor die through the isolated pad.

Implementations of semiconductor packages may include one, all, or any of the following:

The Kelvin bar may be electrically coupled with a Kelvin pin.

Each semiconductor die of the plurality of semiconductor die may include a silicon carbide substrate.

Implementations of the semiconductor package may further include a substrate. The plurality of semiconductor die may be coupled over the substrate and the Kelvin bar and isolated pad may be formed in the substrate.

The plurality of semiconductor die may include four semiconductor die.

The isolated pad may be coupled with a clip.

Implementations of the semiconductor package may include a source clip. The Kelvin pin may be electrically independent from the source clip.

The semiconductor package may include a symmetrical wiring pattern between the isolated pad and each semiconductor die of the plurality of semiconductor die.

Implementations of the semiconductor package may include a gate bar coupled between a gate pin and the plurality of semiconductor die.

Implementations of semiconductor packages may include a plurality of semiconductor die and a Kelvin bar. The Kelvin bar may be U-shaped.

Implementations of semiconductor packages may include one, all, or any of the following:

A plurality of wires extending between the Kelvin bar and the plurality of semiconductor die. Each wire of the plurality of wires may be substantially orthogonal to a length of a source clip extending between the plurality of semiconductor die and a power source.

The plurality of semiconductor die may include four die.

All of the wires of the plurality of wires may run parallel to one another.

Implementations of the semiconductor package may include a gate bar coupled between a gate pin and each semiconductor die of the plurality of semiconductor die.

Implementations of semiconductor packages may include a plurality of semiconductor die, a Kelvin bar, and a plurality of electrical connectors extending between the Kelvin bar and the plurality of semiconductor die. The plurality of wires may run substantially orthogonal to a length of a source clip extending between the plurality of semiconductor die and a power source.

Implementations of semiconductor packages may include one, all, or any of the following:

The plurality of semiconductor die may include three semiconductor die.

The plurality of semiconductor die may include four die.

The Kelvin bar may be formed in a substrate coupled under the plurality of semiconductor die.

Implementations of the semiconductor package may include a gate bar coupled between a gate pin and each semiconductor die of the plurality of semiconductor die.

The plurality of semiconductor die may include silicon carbide.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top view of a first implementation of a semiconductor package;

FIG. 2 is a top view of a second implementation of a semiconductor package;

FIG. 3 is a schematic for a double pulse setup circuit;

FIG. 4 is a graph illustrating the switching loss of the package of FIG. 1 and the package of FIG. 2 in an “on” phase;

FIG. 5 is a graph illustrating the voltage of the package of FIG. 1 and the package of FIG. 2 in an “on” phase;

FIG. 6 is a graph illustrating the amperage of the package of FIG. 1 and the package of FIG. 2 in an “on” phase;

FIG. 7 is a graph illustrating the switching loss of the package of FIG. 1 and the package of FIG. 2 in an “off” phase;

FIG. 8 is a graph illustrating the voltage of the package of FIG. 1 and the package of FIG. 2 in an “off” phase;

FIG. 9 is a graph illustrating the amperage of the package of FIG. 1 and the package of FIG. 2 in an “off” phase;

FIG. 10 is a top view of a third implementation of a semiconductor package;

FIG. 11 is a top view of a fourth implementation of a semiconductor package;

FIG. 12 is a top view of a fifth implementation of a semiconductor package;

FIG. 13 is a top view of a sixth implementation of a semiconductor package;

FIG. 14 is a top view of a seventh implementation of a semiconductor package;

FIG. 15 is a graph illustrating the voltage of the semiconductor package of FIG. 13;

FIG. 16 is a graph illustrating the current of the semiconductor package of FIG. 13;

FIG. 17 is a graph illustrating the voltage of the semiconductor package of FIG. 14; and

FIG. 18 is a graph illustrating the current of the semiconductor package of FIG. 14.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

As semiconductor die, including, but not limited to, die with silicon carbide substrates, are made with process technologies that allow the die to shrink in total die size, existing semiconductor packages that, for example, ordinarily supported two silicon carbide die could now have the physical space to include four silicon carbide die. This ability to include more silicon carbide die in the same package provide various advantages depending on the use of the particular semiconductor package in a particular system. However, the additional die to the same package may cause challenges for measurement and monitoring of the die and the package performance. The ability to drive the dies symmetrically is crucial to the module performance. The source Kelvin is the source path that returns to the gate driver. Therefore, symmetry in the Kelvin scheme is paramount to switching performance.

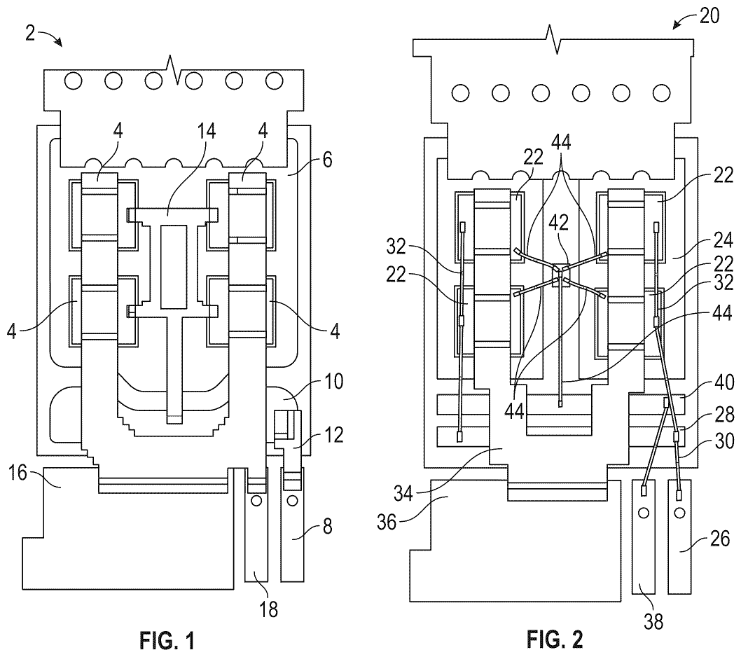

Referring to FIG. 1, a top view of a first implementation of a semiconductor package is illustrated. The package 2 may include a plurality of die 4 coupled over a substrate 6. In various implementations the substrate may be a direct bonded copper (DBC) substrate. In such implementations, the top layer of the substrate may be an active metal brazed (AMB) copper layer.

The semiconductor package 2 includes a gate pin 8 tied to a gate bar 10 via an electrical connection 12. The gate bar 10 may be connected to a gate clip 14 which may couple to gate pads of the plurality of semiconductor die 4.

The semiconductor package 2 includes a power source 16 and a Kelvin pin 18. A power source clip 20 is directly coupled to both the power source 16, the Kelvin pin 18 and the plurality of semiconductor die. The source Kelvin is integrated into the power source clip.

In various implementations, the use of a single clip to connect to the gates of the die and to the Kelvin pin creates an asymmetric source Kelvin scheme that has current imbalance among the die. The integration of the Kelvin pin with the power source clip may cause imbalance in die gate-to-source voltage which leads to imbalance in currents. This imbalance may lead to further problems with operation including higher switching losses, and higher susceptibility to normal switching and Short Circuit oscillations due to high common source inductance and high mutual inductance between the power source and the Kelvin source.

Referring to FIG. 2, a top view of a second implementation of a semiconductor package is illustrated. The package 20 includes a plurality of semiconductor die 22 coupled over a substrate 24. In particular implementations, the plurality of semiconductor die 22 may include two die, four die, or any other number of die.

The substrate 24 may be a DBC substrate having an AMB top layer. In other implementations, the substrate may be a different type of substrate.

The package 20 includes a gate pin 26 tied to a gate bar 28 via an electrical connection 30. The gate bar 28 may be electrically isolated from the remainder of the substrate and have electrical connection only to the gate pin and the gate pads of the plurality of semiconductor die 22. The gate bar may be electrically coupled to the plurality of semiconductor die 22 through a plurality of wires 32. The plurality of wires may be substantially parallel to one another and also to a length of the source clip 34 extending from the power source 36 to the semiconductor die.

The semiconductor package 20 includes a Kelvin scheme including a Kelvin pin 38, a Kelvin bar 40, an isolated pad 42, and Kelvin wiring 44. The Kelvin pin 38 is electrically coupled to the Kelvin bar 40 through a wire or other electrical connection. The Kelvin bar may be electrically isolated from the remainder of the substrate and have electrical connection only to the Kelvin pin 38, the isolated pad 42, and the semiconductor die 22 via the Kelvin wiring 44.

In various implementations, the semiconductor package 20 includes an isolated pad 42. In various implementations disclosed herein, any or all of the isolated pad, Kelvin bar and gate bar may be considered as part of the substrate. In implementations having a DBC substrate, the top layer of the substrate (which may be the AMB layer) may be patterned to form the isolated pad, Kelvin Bar, and gate bar which may all be isolated from the remainder of the substrate due to the insulative layer under the top layer. Any or all of the isolated pad, Kelvin bar and gate bar may be alternatively considered as coupled over the substrate. Under such a consideration, the substrate may be considered the layers below any or all of the isolated pad, Kelvin bar and gate bar.

Still referring to FIG. 2, the package 20 includes Kelvin wiring 44 that extends from the Kelvin bar 40 to the isolated pad 42 and from the isolated pad to the plurality of semiconductor die 22. In various implementations, and as illustrated by FIG. 2, the Kelvin wiring 44 may be symmetrical as it forms a symmetrical pattern between the isolated pad and each semiconductor die of the plurality of semiconductor die.

In other implementations, a clip may be used in place of any or all of the Kelvin wiring.

The package 20 includes a power source 36 and a source clip 34 coupling the power source to a source pad of each die of the plurality of semiconductor die 22. As illustrated, the source clip may be electrically independent from the Kelvin scheme and separated from the Kelvin pin.

The use of the isolated pad 42, the Kelvin bar 40, and the Kelvin wiring 44 allows for decoupling of the Kelvin source driving system from the power source clip. Since the Kelvin monitoring system is electrically separated and symmetric, the die gate to source voltage is tightened which leads to a tighter balance in drain current. This may result in the semiconductor package operating with lower switching losses, low mutual inductance between the power source and the Kelvin source, a low common source inductance, and thus lower susceptibility to oscillations.

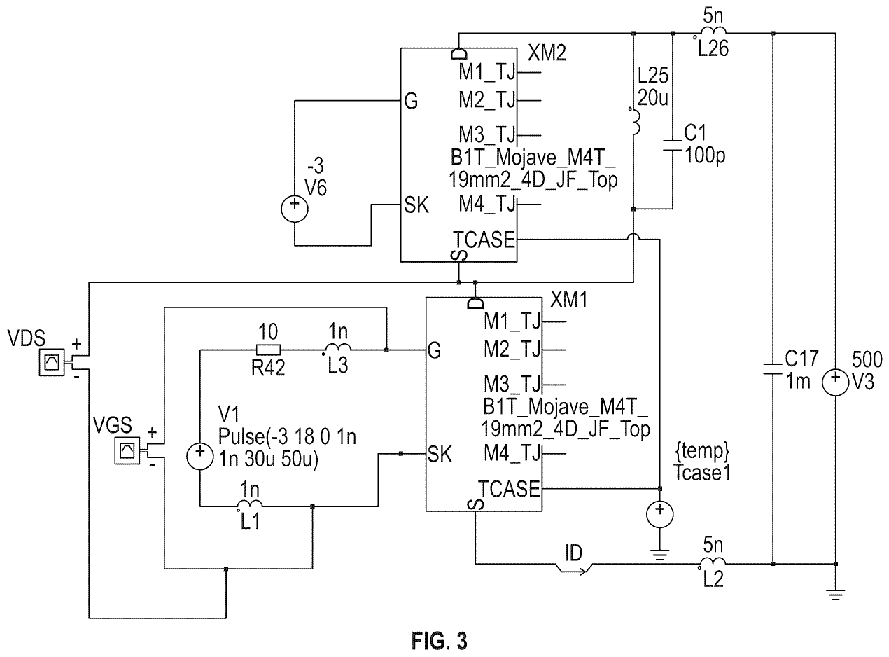

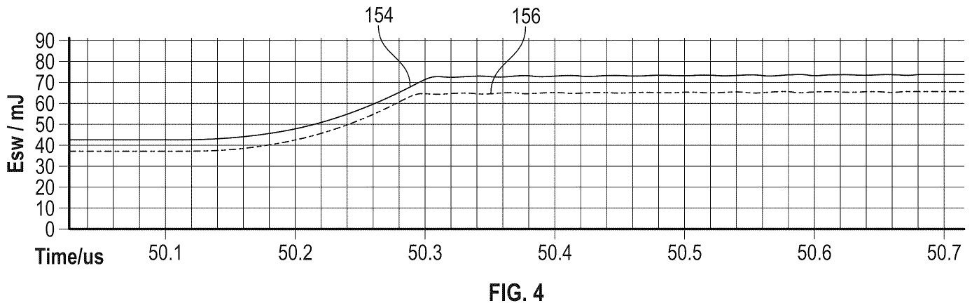

Referring to FIG. 3, a double pulse setup circuit is illustrated. Various electrical tests of the semiconductor package of FIG. 2 were carried out using the standard double pulse setup circuit of FIG. 3. The results of these tests, as compared to respective tests conducted with the semiconductor package of FIG. 1, are illustrated by FIGS. 4-9.

Referring to FIG. 4, a graph illustrating the switching loss of the package of FIG. 1 and the package of FIG. 2 in an “on” phase is illustrated. More specifically, the turn on switching loss is the delta Esw from the transition that happens around 50.2 microseconds. As illustrated, the delta Esw is lower for the package of FIG. 2 than it is for the package of FIG. 1. The solid line 154 represents the performance of the package of FIG. 1 while the dashed line 156 represents the performance of the package of FIG. 2. As illustrated, the package of FIG. 2 shows a 9% improvement in switching losses at the turn on operational condition of the semiconductor package 20.

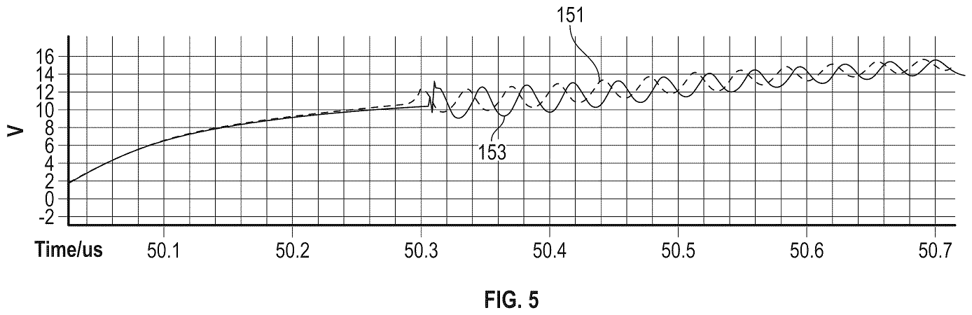

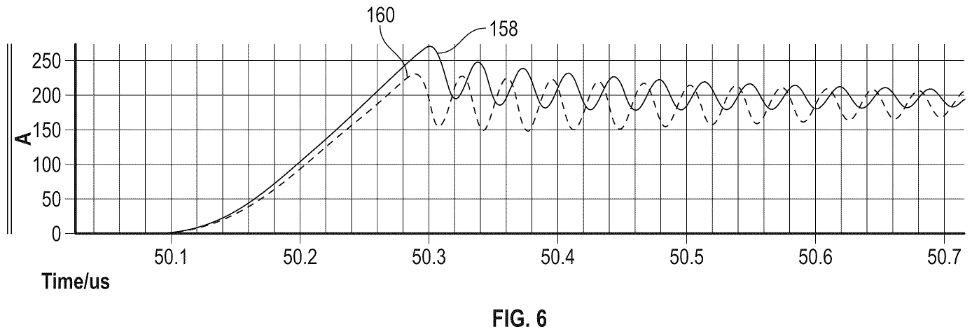

Referring to FIG. 5, a graph illustrating the voltage of the package of FIG. 1 and the package of FIG. 2 in an “on” phase is illustrated. Solid line 153 represents the performance of the package of FIG. 1 while dashed line 151 represents the performance of the package of FIG. 2. Referring to FIG. 6, a graph illustrating the amperage of the package of FIG. 1 and the package of FIG. 2 in an “on” phase is illustrated. FIGS. 5-6 indicate that the simulations showed significantly less magnitude in oscillations between peak to trough currents. For example, solid line 158 of FIG. 6 represents the performance of the package of FIG. 1 while dashed line 160 of FIG. 6 represents the performance of the package of FIG. 2.

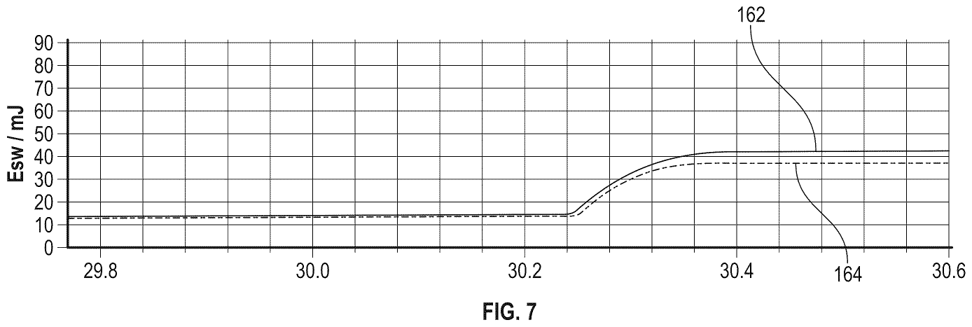

Referring to FIG. 7, a graph illustrating the switching loss of the package of FIG. 1 and the package of FIG. 2 in an “off” phase is illustrated. The solid line 162 represents the performance of the package of FIG. 1 while the dashed line 164 represents the performance of the package of FIG. 2. As illustrated, the package of FIG. 2 shows a 16% improvement in switching losses at the turn off operational condition of the semiconductor package 20.

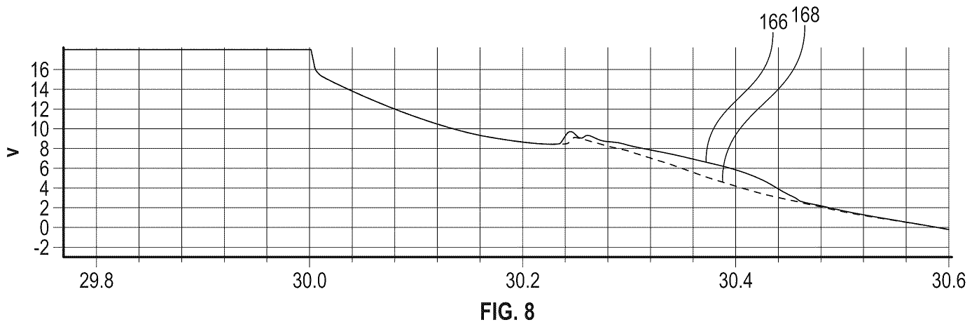

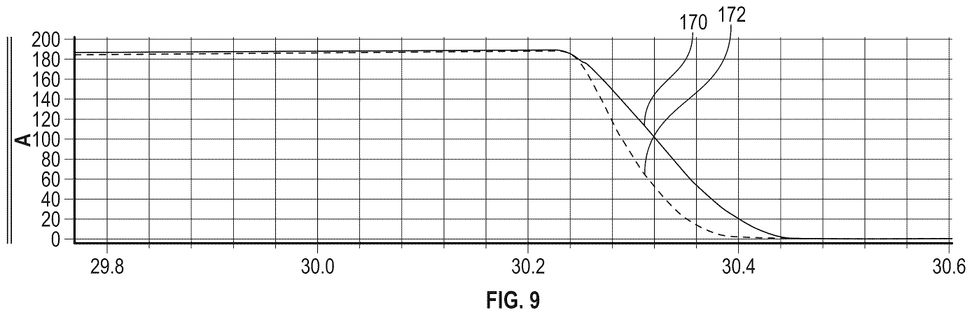

Referring to FIG. 8, a graph illustrating the voltage of the package of FIG. 1 and the package of FIG. 2 in an “off” phase is illustrated. Referring to FIG. 9, a graph illustrating the amperage of the package of FIG. 1 and the package of FIG. 2 in an “off” phase is illustrated. FIGS. 8-9 indicate that, for the turn off operational condition, peak current oscillations were also significantly reduced along with energy consumption. For example, line 166 of FIG. 8 represents the performance of the package of FIG. 1 while the line 168 of FIG. 8 represents the performance of the package of FIG. 2. Similarly, line 170 of FIG. 9 represents the performance of the package of FIG. 1 while line 172 of FIG. 9 represents the performance of the package of FIG. 2.

The thermal performance of the package of FIG. 2 may demonstrate a 2.7% improvement in thermal resistance (RTH) than the package of FIG. 1. Improving Kelvin performance using the Kelvin bar and the isolated pad may significantly improve electrical and thermal performance of the semiconductor package overall.

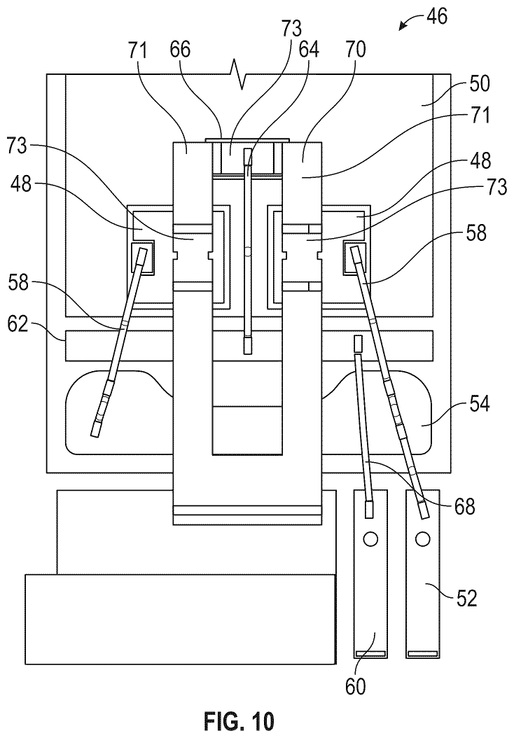

Referring to FIG. 10, a top view of a third implementation of a semiconductor package is illustrated. The package 46 includes two semiconductor die 48 coupled over a substrate 50. The substrate 50 may be a DBC substrate having an AMB top layer. In other implementations, the substrate may be a different type of substrate.

The package 46 includes a gate pin 52 tied to a gate bar 54 via an electrical connection 56. The gate bar 54 may be electrically isolated similar to or the same as other gate bars disclosed herein. The gate bar 54 may be electrically coupled to the plurality of semiconductor die 48 through a plurality of wires 58.

In various implementations, the gate bar 54, as well as any other gate bar or Kelvin bar disclosed herein, could have wider portions to accommodate for wire bonds or attachment points for clips or other electrical connections. In other implementations, any or all of the gate bars or Kelvin bars may have a consistent width across the length of the bar.

The semiconductor package 46 includes a Kelvin system including a Kelvin pin 60, a Kelvin bar 62, an isolated pad 66, Kelvin wiring 64, and a source clip 70. The isolated pad 66 provides a mechanically stable touch down point for the clip where the wires will not go too high into the mold compound formed over the semiconductor die 48. This is a more viable mechanical solution than to contact the Kelvin wire 64 to the high regions of the clip. The Kelvin pin 60 is electrically coupled to the Kelvin bar 62 through a wire 68 or other electrical connection. The Kelvin bar may 62 be electrically isolated from the remainder of the substrate and have electrical connection only directly to the Kelvin pin 60 and the isolated pad 66 through wiring or other electrical connections. Any of the Kelvin wiring 64 may be alternatively replaced with a clip or other electrical connections.

In various implementations, the semiconductor package 46 includes an isolated pad 66. In various implementations disclosed herein, any or all of the isolated pad, Kelvin bar and gate bar may be considered as part of the substrate. In implementations having a DBC substrate, the top layer of the substrate (which may be the AMB layer) may be patterned to form the isolated pad, Kelvin Bar, and gate bar which may all be isolated from the remainder of the substrate due to the insulative layer under the top layer. Any or all of the isolated pad, Kelvin bar and gate bar may be alternatively considered as coupled over the substrate. Under such a consideration, the substrate may be considered as the layers below any or all of the isolated pad, Kelvin bar and gate bar.

Still referring to FIG. 10, the package 46 includes Kelvin wiring 64 that extends from the Kelvin bar 62 to the isolated pad 66. The package 46 also includes a source clip 70. The source clip may be a clip extending from a power source to the plurality of die 48 and also to the isolated pad 66. The source clip 70 may be integrated into the Kelvin measurement system only through the isolated pad 66. As illustrated by FIG. 10, the source clip may include high regions 71 and low regions 73. The low regions may form electrical connections with the isolated pad or semiconductor die. The Kelvin wire 64 may also touch down on the low regions.

As illustrated by FIG. 10, the package 46 includes a fully symmetric source Kelvin scheme/design. The symmetry of this design may provide any of the previously described electrical and thermal performance benefits disclosed herein. In particular the common source inductance is reduced since the Kelvin contact comes in through the source clip 70 at the back of the die where no drain current is flowing. In various implementations, the mutual inductance between the Kelvin and source clip can be reduced by running the Kelvin wire in a scheme orthogonal to the source clip 70 on the outer edges of the substrate.

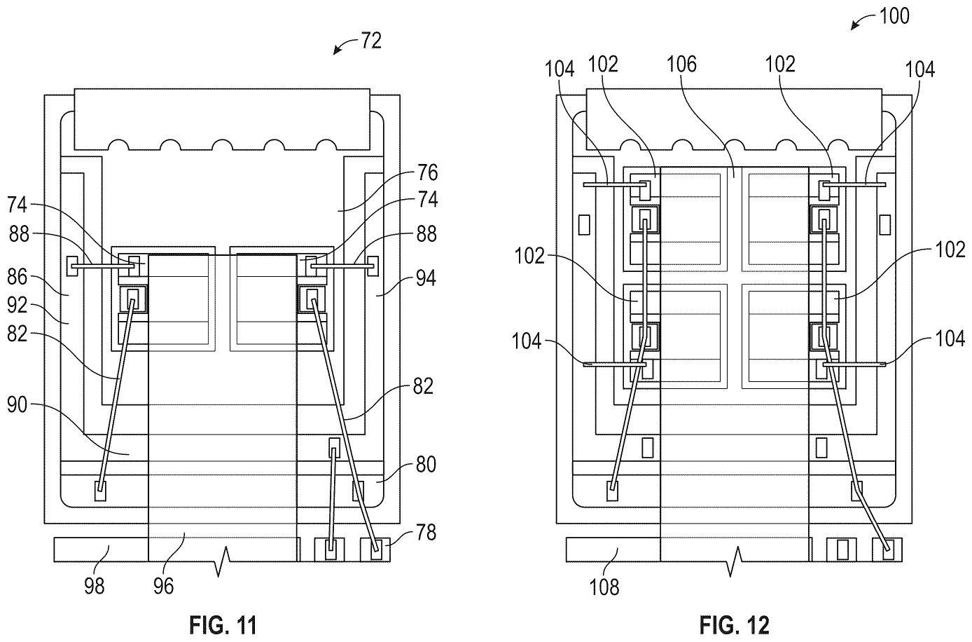

Referring to FIG. 11, a top view of a fourth implementation of a semiconductor package is illustrated. Referring to FIG. 12, a top view of a fifth implementation of a semiconductor package is illustrated. The packages of FIGS. 11-12 both utilize a horseshoe, or U-shaped, Kelvin bar.

Referring specifically to FIG. 11, the package 72 includes two semiconductor die 74 coupled over a substrate 76. The substrate 76 may be a DBC substrate having an AMB top layer. In other implementations, the substrate may be a different type of substrate.

The package 72 includes a gate pin 78 and gate bar 80. The gate pin 78 may be coupled to gate pads of the semiconductor die 74 through electrical connections 82 and the gate bar 80 in the same or a similar manner as any of the implementations of packages disclosed herein.

In various implementations disclosed herein, either or both of the Kelvin bar and gate bar may be considered as part of the substrate. In implementations having a DBC substrate, the top layer of the substrate (which may be the AMB layer) may be patterned to form the Kelvin Bar and gate bar which may all be isolated from the remainder of the substrate due to the insulative layer under the top layer. Either or both of the Kelvin bar and gate bar may be alternatively considered as coupled over the substrate. In such a consideration, the substrate may be considered as the layers below either or both of the Kelvin bar and gate bar.

The package 72 includes a Kelvin measurement system including a Kelvin pin 84, a U-shaped Kelvin bar 86, and Kelvin wiring 88. The Kelvin bar 86 may be electrically isolated from the remainder of the substrate inasmuch as the Kelvin bar is electrically connected to only the Kelvin pin 84 and the semiconductor die 74 through the Kelvin wiring 88. In other implementations, other electrical connections, such as clips, may be used in place of the Kelvin wiring 88.

The U-shaped Kelvin bar 86 includes a base portion 90, first portion 92, and a second portion 94. The first portion 92 and the second portion 94 extend along opposing sides of the plurality of semiconductor die 74. The base portion 90 of the Kelvin bar 86 (which is the portion of the Kelvin bar closest to the source clip) is orthogonal to the length of the source clip. While the first portion 92 and the second portion 94 run parallel to the source clip, because they are relatively distant from the source clip, the mutual inductance between the conductors may remain minimal. The U-shaped Kelvin bar allows for the wiring 88 to be substantially orthogonal to a length of the source clip 96 extending from the power source 98 to the semiconductor die 74. As illustrated, all of the wires extending from the Kelvin bar to the semiconductor die may run substantially parallel to one another.

Referring to FIG. 12, the package 100 may be similar to the package of FIG. 11 with a primary difference being that the package includes four semiconductor die 102 instead of two. In such implementations, package 100 includes wiring 104 that is substantially orthogonal to a length of the source clip 106 extending from the power source 108 to the semiconductor die 102. As illustrated, all of the wires extending from the Kelvin bar to the semiconductor die may run substantially parallel to one another. In various implementations, other electrical connections, such as clips, may be used in place of the Kelvin wiring 104.

While FIG. 12 illustrates four semiconductor die, it is understood that other implementations of packages may include a U-shaped Kelvin bar with more than four semiconductor die, including, by non-limiting example, six die or eight die.

The packages of FIGS. 11 and 12 do not need an isolated pad as the electrical connections extend directly from the Kelvin bar to the semiconductor die. The direct connection between the Kelvin bar and the die may minimize common source inductance. Because the Kelvin bar is in a U-shape, the electrical connections may be orthogonal to the length of the clip. The orthogonal paths may reduce the mutual inductance to the power source path. Further, the Kelvin sensing scheme of the packages of FIGS. 11 and 12 is highly symmetric, which may result in any benefits disclosed herein resulting from symmetrical Kelvin sensing schemes.

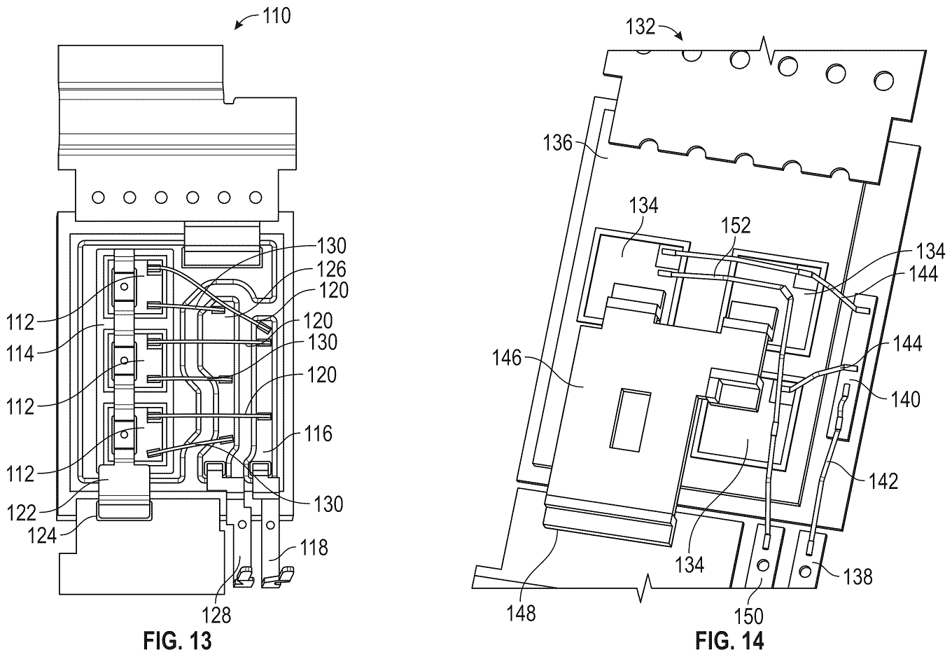

Referring to FIG. 13, a sixth implementation of a semiconductor package is illustrated. The package 110 includes a plurality of die 112 coupled over a substrate 114. The plurality of die may include two die, three die, four die, or more than four die. The substrate 114 may be a DBC substrate having an AMB top layer. In other implementations, the substrate may be a different type of substrate.

The package includes a gate pin tied to a gate bar 116 through an electrical connector 118. The gate bar 54 may be electrically isolated similar to or the same as other gate bars disclosed herein. The gate bar 116 may be electrically coupled to the plurality of semiconductor die 112 through a plurality of wires 120. In other implementations, other electrical connections may be used in place of the plurality of wires 120. In various implementations, any or all of the plurality of wires or electrical connections coupling the gate bar to the semiconductor die may be substantially orthogonal to a length of the source clip 122 extending from a power source 124 to the plurality of die 112.

The semiconductor package 110 includes a Kelvin system including a Kelvin pin connected to a Kelvin bar 126 through an electrical connector 128 and Kelvin wiring 130. The Kelvin bar 126 may be electrically isolated from the remainder of the substrate and have electrical connection only directly to the Kelvin pin and the semiconductor die 112 through wiring or other electrical connections.

In various implementations disclosed herein, either or both of the Kelvin bar and gate bar may be considered as part of the substrate. In implementations having a DBC substrate, the top layer of the substrate (which may be the AMB layer) may be patterned to form the Kelvin Bar and gate bar which may all be isolated from the remainder of the substrate due to the insulative layer under the top layer. Either or both of the Kelvin bar and gate bar may be alternatively considered as coupled over the substrate. In such a consideration, the substrate may be considered as the layers below any or all of the Kelvin bar and gate bar.

The Kelvin wiring 130 (which may be other electrical connectors in other implementations) may be substantially orthogonal to a length of the source clip 122 extending from a power source 124 to the plurality of die 112.

In various implementations, and as illustrated by FIG. 13, the length of the gate bar, Kelvin bar, and source clip may all be substantially parallel to one another.

In the implementation illustrated by FIG. 13, the independent Kelvin measurement system may reduce or eliminate common source inductance. Further, the orthogonal electrical paths between the Kelvin bar and the die and between the power source and the die may reduce mutual inductance.

In various implementations, the source clip 122 may be fine-tuned to optimize current sharing.

Referring to FIG. 14, a top view of a seventh implementation of a semiconductor package is illustrated. The package 132 includes a plurality of die 134 coupled over a substrate 136. The plurality of die 134 may include two die, three die, four die, or more than four die. The substrate 136 may be a DBC substrate having an AMB top layer. In other implementations, the substrate may be a different type of substrate.

The package includes a gate pin 138 tied to a gate bar 140 through an electrical connector 142. The gate bar 140 may be electrically isolated similar to or the same as other gate bars disclosed herein. The gate bar 140 may be electrically coupled to the plurality of semiconductor die 134 through a plurality of wires 144. In other implementations, other electrical connections may be used in place of the plurality of wires 144. In various implementations, any or all of the plurality of wires or electrical connections coupling the gate bar to the semiconductor die may be substantially orthogonal to a length of the source clip 146 extending from a power source 148 to the plurality of die 134.

In various implementations disclosed herein, the gate bar may be considered as part of the substrate. In implementations having a DBC substrate, the top layer of the substrate (which may be the AMB layer) may be patterned to form the gate bar which may be isolated from the remainder of the substrate due to the insulative layer under the top layer. The gate bar may be alternatively considered as coupled over the substrate. In such a consideration, the substrate may be considered as the layers below the gate bar.

The semiconductor package 132 includes a Kelvin scheme including a Kelvin pin 150 and Kelvin wiring 152. In various implementations, the Kelvin pin 150 may be directly coupled to the semiconductor die 134 through the Kelvin wiring 152 without an intermediate Kelvin bar. In various implementations, the Kelvin wiring 152 may include a single wire that touches down on each semiconductor die. In other implementations, the Kelvin wiring may include multiple wires. In still other implementations, other electrical connectors, such as clips, may be used in place of the Kelvin wiring.

The independent Kelvin scheme may result in any benefits to the semiconductor package disclosed herein. More specifically, semiconductor package 132 may have a very low common source inductance and a low mutual inductance between the kelvin wiring 152 and clip as the Kelvin wiring on the top two dies runs orthogonal to the source clip. Further, while the Kelvin wiring 152 is not orthogonal to the clip as it couples over the die closest to the Kelvin pin, the Kelvin wiring 152 is sufficiently distant from the source clip and minimizes the mutual inductance between the Kelvin wiring and the source clip.

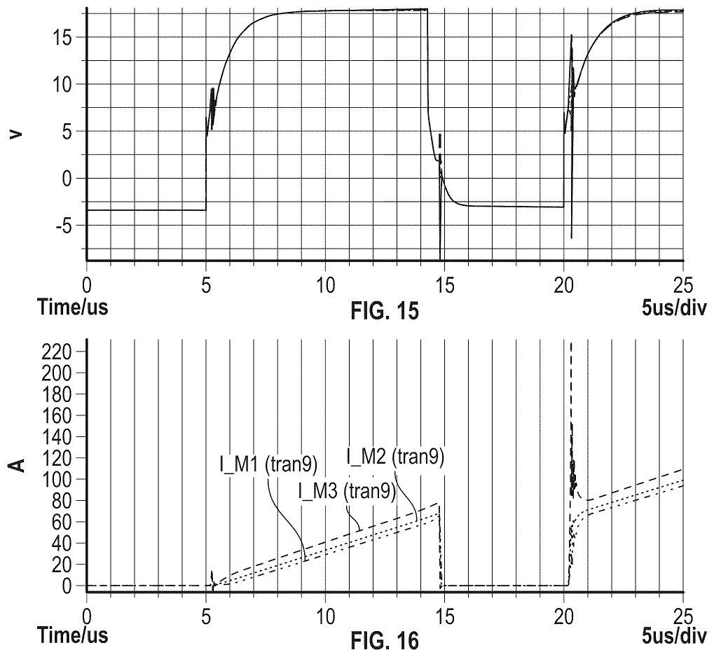

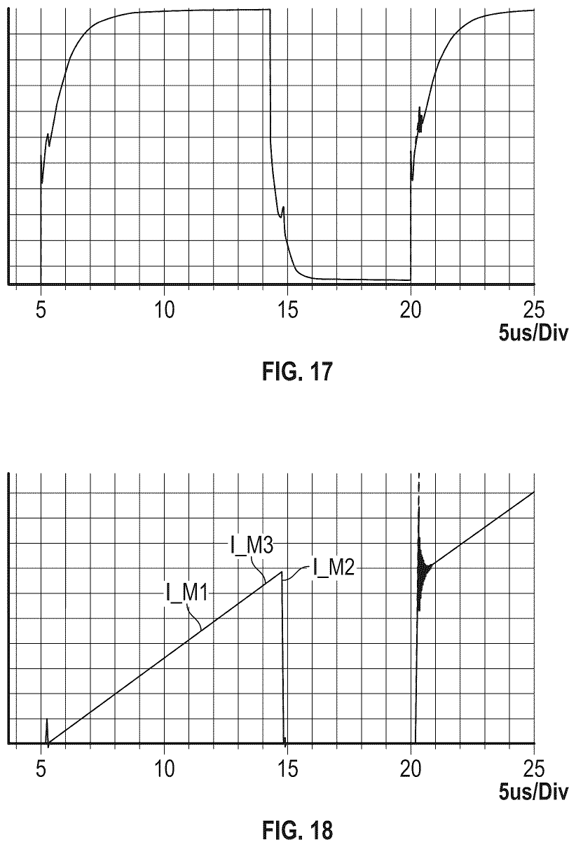

Referring to FIG. 15, a graph of the gate-to-source voltage of the package of FIG. 13 is illustrated. Referring to FIG. 16, a graph of the current of the package of FIG. 13 is illustrated. Referring to FIG. 17, a graph of the gate-to-source voltage of the package of FIG. 14 is illustrated. Referring to FIG. 18, a graph of the current of the package of FIG. 14 is illustrated. These graphs illustrate the improvement in the gate-to-source voltage, ID balancing, and oscillations when comparing the package of FIG. 14 to the package of FIG. 13.

Any of the semiconductor die disclosed herein include silicon carbide substrates. In other implementations, the semiconductor package designs disclosed herein could also use semiconductor die that use any of a wide variety of other semiconductor substrate types including, by non-limiting example, silicon, silicon on insulator, gallium nitride, gallium arsenide, sapphire, ruby, wide bandgap substrate materials, or any other semiconductor substate type. Semiconductor die that include different substrate materials may be utilized in the same semiconductor package.

Any substrates employed in the various semiconductor package implementations disclosed herein may be multi-layer and include a combination of electrically conductive and electrically non-conductive layers. One or more of the layers of the substrates may be patterned.

While the use of wire bonds to connect to the Kelvin bar and/or gate bar have been primarily illustrated herein, a clip or other electrical connector type could also be used to make the connection.

The various semiconductor package implementations disclosed herein could be employed in various systems including power conversion equipment, inverters, and the like. The particular device type for the various semiconductor die disclosed herein may be any of a wide variety, including, by non-limiting example, power semiconductor die, metal oxide field effect transistors (MOSFETs), insulated gate bipolar transistors (IGBTs), diodes, or any other semiconductor device type. The various electrical connectors utilized may include, by non-limiting example, gold, gold alloys, silver, silver alloys, aluminum, aluminum alloys, any combination thereof, or any other electrically conductive material type or alloy thereof. A mold compound may not cover the top surface of the various substrates in various semiconductor package implementations. In various semiconductor package implementations, no mold compound may be employed. The semiconductor die included in the various semiconductor packages may be attached to the substrate(s) and/or leadframe(s) using sintering in various implementations. The semiconductor package types may be cooled on a single side (top side) or on a double side (dual size cooling). In various semiconductor package types, one or more semiconductor die may be embedded in one or more of the substrates or layers of the package thereof.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
a plurality of semiconductor die;
a Kelvin bar; and
an isolated pad;
wherein the Kelvin bar is electrically coupled to the plurality of semiconductor die through the isolated pad.

2. The semiconductor package of claim 1, wherein the Kelvin bar is electrically coupled with a Kelvin pin.

3. The semiconductor package of claim 1, wherein each semiconductor die of the plurality of semiconductor die comprises a silicon carbide substrate.

4. The semiconductor package of claim 1, further comprising a substrate, wherein the plurality of semiconductor die are coupled over the substrate and the Kelvin bar and isolated pad are formed in the substrate.

5. The semiconductor package of claim 1, wherein the plurality of semiconductor die comprises four semiconductor die.

6. The semiconductor package of claim 1, wherein the isolated pad is coupled with a clip.

7. The semiconductor package of claim 2, further comprising a source clip, wherein the Kelvin pin is electrically independent from the source clip.

8. The semiconductor package of claim 1, wherein the semiconductor package comprises a symmetrical wiring pattern between the isolated pad and each semiconductor die of the plurality of semiconductor die.

9. The semiconductor package of claim 1, further comprising a gate bar coupled between a gate pin and the plurality of semiconductor die.

10. A semiconductor package comprising:
a plurality of semiconductor die; and
a Kelvin bar;
wherein the Kelvin bar is U-shaped.

11. The semiconductor package of claim 10, further comprising a plurality of wires extending between the Kelvin bar and the plurality of semiconductor die, wherein each wire of the plurality of wires is substantially orthogonal to a length of a source clip extending between the plurality of semiconductor die and a power source.

12. The semiconductor package of claim 11, wherein the plurality of semiconductor die comprises four die.

13. The semiconductor package of claim 11, wherein each wire of the plurality of wires run parallel to one another.

14. The semiconductor package of claim 11, further comprising a gate bar coupled between a gate pin and each semiconductor die of the plurality of semiconductor die.

15. A semiconductor package comprising:
a plurality of semiconductor die;
a Kelvin bar; and
a plurality of electrical connectors extending between the Kelvin bar and the plurality of semiconductor die;
wherein the plurality of electrical connectors run substantially orthogonal to a length of a source clip extending between the plurality of semiconductor die and a power source.

16. The semiconductor package of claim 15, wherein the plurality of semiconductor die comprises three semiconductor die.

17. The semiconductor package of claim 15, wherein the plurality of semiconductor die comprises four die.

18. The semiconductor package of claim 15, wherein the Kelvin bar is formed in a substrate coupled under the plurality of semiconductor die.

19. The semiconductor package of claim 15, further comprising a gate bar coupled between a gate pin and each semiconductor die of the plurality of semiconductor die.

20. The semiconductor package of claim 15, wherein the plurality of semiconductor die comprise silicon carbide.
